(19) United States
(12) Patent Application Publication
(10) Pub. No.: US 2001/0039098 A1
(43) Pub. Date: Nov. 8, 2001

(54) Method for fabricating silicon-on-insulator material

(76) Inventor: Zhiheng Lu, Beijing (CN)

Correspondence Address: MANELLI DENISON & SELTER, 2000 M STREET NW SUITE 700, WASHINGTON, DC, 20036-3307, US

(21) Appl. No.: 09/838,316

(22) Filed: Apr. 20, 2001

(30) Foreign Application Priority Data
Apr. 24, 2000 (CN) 00106246.8

(51) Int. Cl. H01L 21/76; H01L 21/425

(52) U.S. Cl. 438/407; 438/423; 438/517

(57) ABSTRACT

This invention discloses a method for fabricating SOI material, incorporating an amorphous process introduced by ion implantation in the conventional SIMOX methods, which enhances diffusion of various atoms in the amorphous region in annealing process. It realizes under a lower temperature annealing to eliminate threading dislocations and other crystal defects in the top silicon layer and silicon islands, pinholes and other silicon segregation products in the buried oxide layer and fabricate high quality of SOI material. Another method for forming SOI material is also described, incorporating an amorphous process introduced by ion implantation in the SIMNI or SIMON methods. It forms amorphous buried nitride or oxynitride layer, a top single crystal silicon layer and a sharp interface between the top layer and the buried layer.

This application claims priority to Chinese Patent Application No. 00106246.8, filed on Apr. 24, 2000, the complete disclosure of which is incorporated herein by reference.

### FIELD OF THE INVENTION

The present invention relates generally to semiconductor material technology field, and more particularly to a method of separation by implantation of oxygen (SIMOX) and separation by implantation of nitrogen processes (SIMNI) to fabricate silicon-on-insulator (SOI) materials.

### BACKGROUND OF THE INVENTION

A great deal of investigation shows that the development of dense integration of semiconductor devices on conventional bulk silicon wafer have encountered many difficulties, especially in the development of very large scale integrated circuits (VLSI) with the gate length of 0.1 μm or less, such as parasitic capacitance, parasitic latch-up and so on.

Because the top silicon layer of the silicon-on-insulator (SOI) is very thin, it has the following advantages over a bulk Si wafer:

It can be used in the fabrication of VLSI having a gate length of 0.1 μm or less for reducing various parasitic effects, which exist in the high dense integration of semiconductor devices on conventional bulk silicon wafer.

It can be used in the fabrication of high speed and low power dissipation semiconductor devices required by various portable devices.

It can be used in the fabrication of irradiation-hardened semiconductor devices.

Therefore, it is well believed that SOI material will be the VLSI material of choice in the coming 21 century.

SIMOX is a main method for fabricating SOI material at present. It comprises the main steps of: implanting large dose of oxygen ion into a single crystal silicon wafer and subsequently annealing it at a high temperature above 1300° C. to form a buried oxide layer (BOX) in the silicon wafer, which isolates the top Si layer, including major surface from the bottom single crystal Si substrate. Semiconductor devices are fabricated on the top Si layer, the thickness of which is about 100 nm to about 200 nm.

In SOI material fabricated by conventional SIMOX methods, there are two problems which negatively affect the product quality. One problem is the presence of threading dislocations in the top Si layer. Typically, the threading dislocation density is higher than 1×10⁷cm⁻². These threading dislocation degrade the electrical properties of device fabricated on the layer. Another problem is the presence of silicon islands and pinholes. These silicon segregation products, formed in the buried silicon oxide layer, greatly reduce the insulating property of the BOX.

The mechanism of forming a high density of threading dislocations relates to the high dose implantation of oxygen. In order to form sufficient thickness of the buried silicon oxide layer, a very large dose of O⁺ ions, such as 1.2×10¹⁸cm⁻² to 1.8×10¹⁸cm⁻², cm is required. At the same time, an implantation-energy from 150 keV to 200 keV is required to provide sufficient thickness of the top Si layer. Such implantation of oxygen into silicon wafer at room temperature will form an amorphous region within the range of implantation, which will spread to the major surface. After annealing, the whole top silicon layer becomes polycrystalline silicon, but not the required single crystal silicon. In order to keep single crystal structure in vicinity of the major surface, the wafer must be heated to a temperature in the range of 450 to 700° C. during implantation. Therefore, during the annealing process, a recrystallization process will start at a major surface and then form a single crystal structure on the whole top Si layer. However, because the wafer is heated, implanted oxygen atoms firstly combine with silicon atoms to form silicon dioxide in the implanted ion concentrated region and then the silicon dioxide region will spread further with the increase of implantation dose. From a macroscopical point of view, the substitution of silicon with oxygen will produce accessional stress because of the increase in volume. From a microscopical point of view, a part of the substituted redundant silicon atoms will transfer to the top layer, where they become interstitial atoms. Another part of the substituted redundant silicon atoms will precipitate within the buried oxide layer and form a silicon segregation product, such as silicon islands and pinholes in the subsequent annealing process. Because the statistical distribution of the implanted oxygen is close to Gauss distribution, a small part of oxygen atoms exist at the top silicon layer, which combine with the nearby silicon atoms and form silicon dioxide grain. Furthermore, irradiation damage, especially the complex of various defects formed by irradiation damage at high implantation temperature, is difficult to eliminate in the subsequent annealing process. In order to restore single crystal silicon in the top silicon layer with such complicated defects, the annealing temperature has to be increased almost to the melting point of single crystal silicon (1420° C.). However, the formed threading dislocations cannot be eliminated even at such high temperature.

As described by J. Stoemenos et al. in the article “Dislocation formation related with high oxygen dose implantation on silicon” pubished in J. Appl. Phys, 69(1991), p.793, silicon dioxide grains are dissolved during annealing at high temperature, and oxygen atoms move to the buried oxide layer and combine with Si atoms at the interface to form SiO₂, which become a portion of buried oxide layer. The remaining interstitial Si atoms will produce threading dislocations in the annealing process.

The density of the threading dislocations depends on the oxygen ion implantation conditions. A higher dose of oxygen ion tends to increase the dislocation density. Instead of a high dose implantation and subsequent annealing at high temperature, a multi-steps process of lower dose implantation below 0.4×10¹⁸cm⁻², with annealing at high temperature every time, has been proposed by D. Hill et al. in publication in J. Appl. Phys., 63(1988), p. 4933, “The reduction of dislocations in oxygen implanted silicon on insulator layers by sequential implantation and annealing”. As reported, the dislocation density on the top layer can be reduced to 1×10³cm⁻². But this technique is expensive and, thus, restricted in the commercial application.

The mechanism for production of Si islands and pinholes is not very clear heretofore. The pressure caused by a surface tension in Si islands prevents silicon atoms from diffusing outwards, which is the main reason for Si islands retention. This was a widely accepted explanation until now.

Currently, there is no effective method for eliminating Si islands. However, it is well known that a low dose of oxygen implantation forms a thinner buried oxide layer and reduces the density of Si islands. An investigation of oxygen implantation of low dose is under way based on this fact. As published in the article in J. Electrochem. Soc., 143(1996), p.244, “Investigations on high-temperature thermal oxidation press at top and bottom interfaces of top silicon of SIMOX wafers”, S. Nakashima et al. show that while annealing the silicon wafer implanted by low oxygen dose in an oxidation ambient of Ar₂ and O₂ mixture, the internal interface of the top silicon layer with the buried oxide layer will be oxidized at the same time as oxidation on the surface of silicon wafer. It will increase the thickness of buried oxide layer and restrain the generation and increase of silicon islands and pinholes at the same time, which is referred to as an inner thermal oxidation method (ITOX). However, because the inner oxidation rate is very slow, the external oxidation consumes the top silicon layer more rapidly, which undesirably confines the application prospects of the ITOX.

As for the formation mechanism of silicon islands or pinholes, one has overlooked such fact, that it is a segregation of silicon in the buried oxide layer in an ultra-high temperature annealing in a given initial condition. Because the combination bond between oxygen atom and silicon atom is very strong in the buried oxide layer, it is very difficult for either oxygen atoms or silicon atoms to migrate in the layer. Therefore, once the silicon islands, pinholes or other silicon segregation products are formed, it is very difficult to eliminate them whether surface tension is created or not.

Separation by implantation of nitrogen processes (SIMNI) has also been proposed to form a silicon-on-insulator (SOI) material, which uses nitrogen as the implantation atom instead of oxygen. Because the ratio of nitrogen with silicon in Si₃N₄ is much lower than that of oxygen with silicon in SiO₂, a relatively few nitrogen ions is required to form the buried insulating layer of the same thickness, which will reduce the cost and dislocation density in the top layer. However, the buried nitride layer formed in high-temperature annealing is polycrystalline α-Si₃N₄, which leads to larger leakage currents and worse insulating characteristics.

In order to overcome the aforesaid disadvantages, in the article of “Microstructure of silicon implanted with high dose of nitrogen and oxygen” published in J. Electrochem. Soc., 133(1986), p.1186, L. Nesbit et al. pointed out that an amorphous buried oxynitride layer can be formed by implantation of nitrogen and then an additional implantation of oxygen at the same energy. But when the additional implanted oxygen dose is lower, a polycrystalline silicon layer will be formed in the top silicon layer near the amorphous buried oxynitride layer, which makes it impossible to form a sharp interface. On the other hand, when the additional implanted oxygen dose is higher, nitrogen bubbles will be formed in the buried layer, which concerns the low diffusion coefficient of nitrogen atom in silicon nitride and silicon oxynitride.

### SUMMARY OF THE INVENTION

An objective of the present invention is to introduce an amorphous process by ion implantation for fabricating a high quality of silicon-on-insulator material in the separation by implantation of oxygen (SIMOX) and the separation by implantation of nitrogen (SIMNI) methods, while overcoming the above-described disadvantages.

It is well known that the ion implantation process is a collision process with atoms in wafer. If the energy of the implanted ion in the collision process is large enough to break the combination bond of the collided atom with its neighboring atom, the atom in a crystal lattice of wafer will move out from its original site and the single crystal or polycrystalline region will turn into an amorphous region if the implantation dose is large enough. Although not all the atoms become isolated or discrete in the amorphous region, the original connection weakens. These atoms can migrate in significantly more interstices and channels with very low activated energy in a subsequent annealing process, at least in the beginning of the annealing process. Therefore, an amorphous process by ion implantation has an enhanced diffusion effect.

Based on the aforesaid idea, the present invention provides a method for the separation by implantation of oxygen to form a high quality silicon-on-insulator material on a silicon containing a substrate having a major surface, which comprises the steps of:

(1) implanting oxygen ions at a first dose and a first energy through said major surface into said silicon containing substrate controlled at a first temperature;

(2) implanting second kind of ions at a second dose and a second energy through said major surface into said silicon containing substrate at a second temperature below 100° C., to form an amorphous region beneath the major surface and to keep the original structure in the major surface of said silicon containing substrate; and

(3) annealing the silicon containing substrate at a third temperature to form a buried oxide layer by combining oxygen implanted in step (1) with silicon in the substrate and the top silicon layer including the said major surface is isolated by the buried oxide layer.

When the third temperature of annealing process in the step (3) is chosen to be in the region from 1250° C. to below silicon melting point, it will eliminate the threading dislocations in the top silicon layer, but the silicon islands and pinholes in buried oxide layer still exist.

When the third temperature of annealing process in the step (3) is chosen to be a proper one in the region from 900° C. to 1250° C. with a proper period of annealing time selected in the range from 1 second to 20 hours, it will eliminate either the threading dislocations in the top silicon layer or the silicon islands and pinholes in buried oxide layer to form SOI material.

The present invention has changed the initial condition formed by the oxygen ion implantation process. Under the condition of keeping the single crystal structure in the vicinity of major surface of silicon including substrate, the present invention performs the amorphous process by ion implantation, to form the amorphous layer containing both a majority of top silicon layer and all the buried oxide layer. Because of the amorphous effect, the top silicon layer will rapidly recrystalize from the major surface during the annealing process. A lot of interstitial atoms in top silicon layer rapidly return to a lattice position, so as to eliminate the production of threading dislocations. Furthermore, the atoms, either oxygen atoms or silicon atoms, have enhanced diffusion effect in the annealing process and, therefore, annealing can be performed at significantly lower temperatures than the annealing temperature required by conventional methods. The claimed process reduces the threading dislocations in top silicon layer, as well as the silicon islands and pinholes in the buried oxide layer, to form a high quality of SOI material.

Also based on the aforesaid idea, the present invention provides another method of the separation by implantation of nitrogen to form high quality of silicon-on-insulator material on a silicon containing substrate having a major surface, which comprises the steps of:

(1) implanting nitrogen ions at a first dose and a first energy through said major surface into said silicon containing substrate controlled at a first temperature;

(2) implanting second kind of ion at a second dose and a second energy though said major surface into said silicon containing substrate at a second temperature below 100° C. to form an amorphous region beneath said major surface in majority of top silicon layer and retain an original structure in said major surface of the silicon containing substrate, and to enhance the diffusion of atoms in the amorphous region; and

(3) annealing the silicon containing substrate at a third temperature in the range from 900° C. to below the melting point of silicon, to combine the first implanted nitrogen and silicon to form a buried nitride layer and the top silicon layer, including the major surface isolated by the buried nitride layer.

According to the method, before step (2) it may further comprise an oxygen implantation using an energy the same as the first energy. The implantation dose can be chosen in the range from 1.0×10¹⁶cm⁻² to 1.0×10¹⁸cm⁻² to form a buried oxynitride layer in said annealing process of step (3), which will be a desired amorphous structure.

Because of the enhanced diffusion effect of various atoms in the amorphous region it is possible, at lower temperatures, to form an amorphous buried nitride layer having a clear interface. In the additional implantation of oxygen process, because of the recrystallization in the top silicon layer and the enhanced diffusion effect of various atoms in the amorphous region, it is possible to form the top silicon layer as a single crystal having a sharp interface and buried layer as amorphous without nitrogen bubble in this region. Therefore, using the separation by implantation of nitrogen processes, one is able to fabricate a high quality SOI material and to reduce manufacturing cost.

The first dose of first implanted ion is chosen to form the buried oxide layer, buried nitride layer or buried oxynitride layer having a desired thickness after the annealing process in step (3).

The said first energy of first implanted ion is chosen to form the buried oxide layer, buried nitride layer or buried oxynitride layer with enough depth after the annealing process in step (3), so as to form the top silicon layer having a desired thickness.

The first temperature is preferably chosen to retain the original structure of the major surface on silicon containing substrate in the first implantation process.

The second kind of ion is preferably chosen to avoid influencing the character of substrate material after annealing process. Suitable examples include silicon ions, germanium ions, inert gas ions, oxygen ions, etc.

Based on the aforesaid idea, the present invention also provides a method for eliminating silicon islands and pinholes in the buried oxide layer of SOI material formed by using any separation by implantation of oxygen process, which comprises the steps of:

(1) implanting silicon ion, germanium ion, inert gas ion or oxygen ion at an energy and a dose into SOI material with top silicon layer and buried oxide layer at a temperature below 100° C. to form an amorphous region including a buried oxide layer and to retain the original structure in vicinity of the major surface;

(2) annealing the SOI material at a temperature in the range from 900° C. to 1250° C. to restore the structure of SOI material and to eliminate silicon islands and pinholes in the buried oxide layer.

Because of the amorphous process of whole buried oxide layer with silicon islands and pinholes and subsequent annealing at a lower temperature in the range from 900° C. to 1250° C., the silicon islands are eliminated and the pinholes density decreases enormously in the SOI material.

Thus, it can be seen that the present invention not only solves the problems of silicon islands and threading dislocation, but also significantly decreases the cost for fabricating SOI material by using conventional annealing furnace and lower annealing temperature instead of the expensive high temperature (over 1300° C.) furnace, which is made of SiC tube.

### BRIEF DESCRIPTION OF THE DRAWINGS

These and other features, objects and advantages of the present invention will become apparent upon consideration of the following detailed description of the invention when read in conjunction with the drawing in which:

FIG. 1 shows an illustration of the random spectrum of Rutherford Backscattering Spectroscopy (RBS) of a SOI material fabricated by conventional method the routine process. It can be seen that the thickness of the formed top silicon layer is about 200 nm and the thickness of the buried oxide layer is about 300 nm.

FIG. 2 shows an illustration of an RBS channeling aligned spectrum of the sample, on which amorphous process is performed by a silicon self implantation. It can be seen that the amorphous region in the depth within 50 nm to 500 nm beneath the surface.

FIG. 3 is a cross-sectional transmission electron micrograph (XTEM) of the sample, on which amorphous process is performed by a silicon implantation after an implantation of oxygen ion with dose of 1.6×10¹⁸cm⁻² and energy of 170 keV into p-type (100) Si wafer, and then performed by rapid thermal annealing at temperature of 1150° C. for 5 seconds. It can be seen that SOI three-layer structure has been formed primarily. The top silicon layer has been recrystallizing. There are no silicon islands in the buried layer.

FIG. 4 is a cross-sectional transmission electron micrograph of a sample treated as in FIG. 3 except for 5 seconds of rapid thermal annealing at temperature of 1250° C. It can be seen that the SOI three-layer structure with clear interface has been formed. Si islands have appeared in the buried layer.

FIG. 5 is a cross-sectional transmission electron micrograph of the sample, on which amorphous process is performed by a silicon implantation after an implantation of oxygen ion with dose of 1.6×10¹⁸cm⁻² and energy of 180 keV into p-type (100) Si wafer and subsequent annealing at temperature of 1300° C. for 6 hours. It can be seen that there are silicon islands, but no threading dislocations in the SOI material.

FIG. 6 is a cross-sectional transmission electron micrograph of a sample treated as in FIG. 5 except for annealing at a lower temperature in the region from 900° C. to 1250° C. It can be seen that there are no threading dislocations or silicon islands in the SOI material.

FIG. 7 is a cross-sectional transmission electron micrograph of a sample, which is formed as in FIG. 5 and then silicon self-implantation is performed for forming amorphous region and subsequently annealed at a temperature in the range from 900° C. to 1250° C. It can be seen also that there are no threading dislocations or silicon islands in the SOI material.

### DETAILED DESCRIPTION OF THE INVENTION

Based on amorphous process the improved SIMOX method is realized to form SOI material as follows:

At first, the silicon wafer mounted to a holder as a target is heated to a temperature in the range from 450° C. to 700° C., preferably about 500° C. It is heated usually by a set of halogen lamps in an implant chamber. The temperature of the target is kept constant by the electronic device during implantation. The wafer may be p-type (100) silicon or n-type silicon, or with other orientation as desired. Oxygen ions are implanted into silicon substrate through the polished surface, or said major surface. The dose of implanting oxygen ion is usually in the region from 1×10¹⁶cm⁻² to 5×10¹⁸cm⁻². Conventionally, the dose in the region from 1.2×10¹⁸cm⁻² to 1.8×10¹⁸cm⁻² is chosen to form buried oxide layer of thickness in the region from about 300 nm to about 400 nm. In the present invention, a lower dose may be chosen to form a thinner buried oxide layer. For example, a dose of 0.5×10¹⁸cm⁻² may correspond to the thickness of about 100 nm. The implantation energy is usually chosen in the region from 30 keV to 400 keV, depending on both the thickness of the top silicon layer and the thickness of the formed buried oxide layer. Conventionally, the implantation energy is chosen in the region from 150 keV to 180 keV for forming a thickness of about 200 nm of the top silicon layer and a desired thickness of buried oxide layer. In many cases, a silicon dioxide film with thickness from 0 to 100 nm is deposed on the polished surface of silicon wafer before ion implantation. On one hand, it can prevent silicon wafer from the direct contamination of metal grain during ion implantation process. On the other hand, it can protect the smooth silicon surface when the silicon dioxide film is removed after ion implantation process. However, the silicon dioxide film should not to be too thick, because reduction of the thickness of the top silicon layer is the cost for this process. For example, a suitable thickness of the silicon dioxide film is about 50 nm.

Following is the second ion implantation process for performing the amorphous process. It is performed after reducing the temperature of target or in another implanter. The temperature of target is usually selected to be lower than 100° C. in this process, because the lower the target temperature, the wider the amorphous region at the same implantation dose. It is convenient if the target temperature is selected as about room temperature, more preferably at liquid nitrogen temperature (about 77 K). For the amorphous process, the implanting ion may be chosen to be silicon ion, germanium ion, inert gases ion or oxygen ion. The silicon ion is preferred. Because silicon ion implantation is the self-implantation for a silicon wafer, it will not affect the quality of the silicon wafer if the irradiation damage is restored in the annealing process. The others, germanium ion can be used because it is the element in same group as silicon and has an infinite solid solubility in silicon. Inert gas ions can be used because the do not react with any other element, so they do not affect the quality of the silicon wafer when used in a small dose. Oxygen ion can be used because it is the same ion as that in the first implantation step and plays the same role in the subsequent annealing process.

After the selection of the implanting ions, the width of the amorphous region will be mainly determined by the dose of implanting ion and the temperature of the wafer. In order to get high amorphous efficiency, the wafer temperature is confined below 100° C. Because the high temperature of the target will cause the sample annealing to restore the irradiation damage, that will reduce the amorphous region. The second implantation energy mainly determines the depth of the amorphous region. In this process, the implantation energy is chosen in the region from 30 keV to 5 MeV, the implantation dose is chosen in the region from 1×10¹³cm⁻². In the conventional SIMOX method of thick buried oxide layer, silicon ion is selected as the second implanted ion, the implantation energy is chosen in the region from 100 keV to 500 keV and the dose is chosen in the region from 5×10¹³cm⁻² to 5×10¹⁶cm⁻². The implantation energy and dose are so selected, that the amorphous layer can contain both a majority of top silicon layer and all the buried oxide layer under the condition of keeping the single crystal structure in the vicinity of major surface of silicon. According to Richmond's or Sigmund's theory, the implantation energy and dose may be calculated at first based on the decision of the thickness and the depth of the amorphous region, and then they may be validated by the RBS channeling effect.

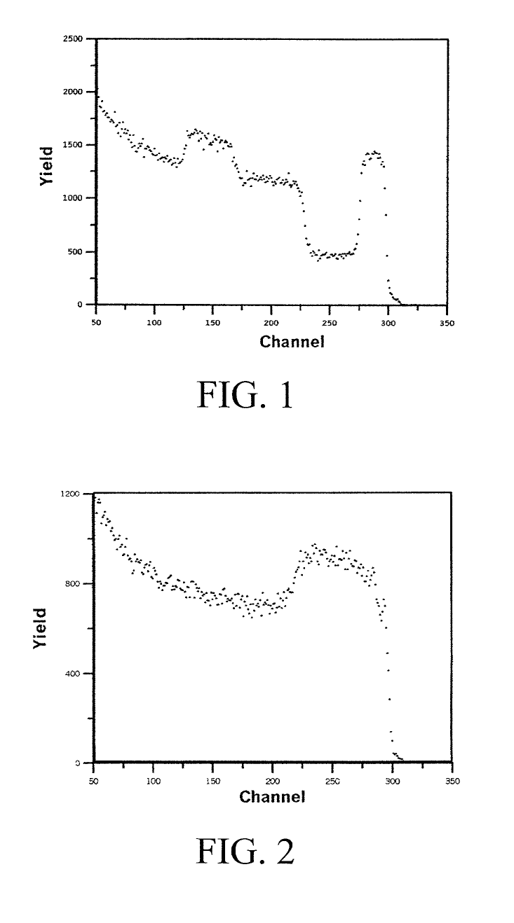

The RBS spectra presented in FIG. 1 and FIG. 2 are used to analyze the results, which were acquired using an incident beam of 2.0 MeV He⁺ ions normal to the sample's surface and a detector positioned at an angle of 165° with incident beam. In both figures, the ordinate represents backscattering yield (counts) and the abscissa represents the channel number in the multi-channel analyzer. In the experimental condition, the depth of every channel is about 8.3 nm. FIG. 1 shows the RBS random spectrum of a SOI sample made from a p-type (100) Si wafer after oxygen ion implantation and subsequent high-temperature annealing. The ion implantation was done at an energy of 180 keV and a dose of 1.6×10¹⁸cm⁻². The annealing was conducted for 6 hours at 1300° C. It is shown in the figure that the thickness of the top silicon layer is about 200 nm and the thickness of the buried oxide layer is about 300 nm. As shown in the channeling aligned spectrum of FIG. 2, the depth of amorphous region is in the range from about 50 nm to about 500 nm. The peak in right side of the spectrum especially showing single crystal structure on the surface of the silicon wafer is clearly visible. The height of the peak increases because the channeling spectrum of the surface adjacent to heavy damaged region overlaps with that of amorphous region.

Subsequent is the third step, the annealing process. In order to prevent the implanted oxygen from escaping out of the wafer and retain the smooth surface during high temperature annealing, a silicon dioxide film with thickness from just about 0 to about 500 nm was deposed on the implanted sample at a temperature below 700° C. Preferably, a thickness of about 200 nm to about 300 nm is selected. Subsequent annealing is performed in an inert ambient nominally mixed with less than 2 percent of oxygen. The annealing temperature can be from about 1250° C. to below the melting temperature of silicon, with the duration from about 1 to about 10 hours.

The top silicon layer rapidly recrystallizes starting from the major surface because of the amorphous enhanced diffusion effect. In this recrystallization process a lot of interstitial silicon atoms in the top silicon layer rapidly return to the lattice position of the silicon single crystal, which eliminates the causes for forming the threading dislocations, based on the amorphous enhanced diffusion effect. At the same time the silicon oxide grains in the top silicon layer are dissolved, the dissolved oxygen atoms in the top silicon layer rapidly migrate to the buried oxide layer, driven by chemical potential. This process restores the single crystal structure in the top silicon layer. All of these result in elimination or at least a significant reduction of threading dislocation and formation of a SOI material with a sharp and smooth interface. However, there can be silicon islands and pinhole in the buried oxide layer as shown in FIG. 5.

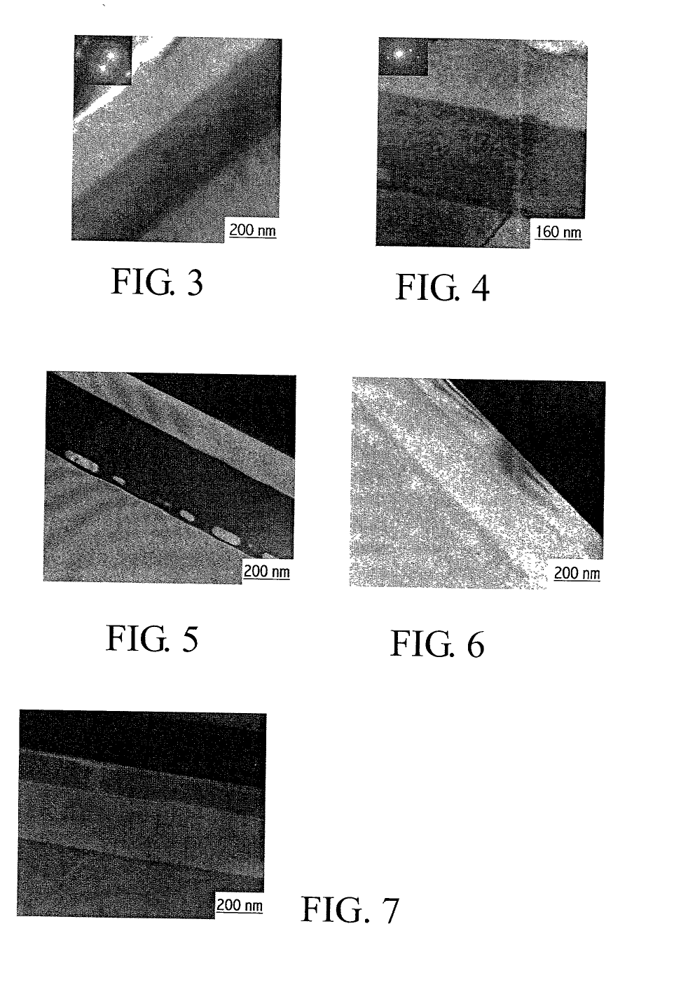

Referring now to the XTEM photographs in FIG. 3 and FIG. 4, it can be seen that an SOI three-layers structure has been formed primarily after a conventional oxygen ion implantation process and a subsequent amorphous process by silicon ion implantation. The top silicon layer has been being recrystallized during the rapid thermal annealing at 1150° C. for 5 seconds, and there do not emerge silicon islands in the buried layer. After the rapid thermal annealing at 1250° C. for 5 seconds, the SOI three-layer structure has clear interfaces. Silicon islands do emerge in the buried layer, but there are no threading dislocations in the top silicon layer. It shows further that silicon islands in buried oxide layer are the products of the segregation of silicon in high temperature annealing and that the threading dislocations do not emerge in top Si layer of the amorphous process by silicon ion implantation. It may also be seen in FIG. 3 and FIG. 4 that a band of damage appears in silicon substrate subjacent the buried oxide layer. It is denominated as ion implantation end-of-range damage (EOR), which is caused by the insufficiency of annealing.

FIG. 5 is an XTEM photograph of a sample made from p-type (100) silicon, which is formed by oxygen ion implantation at dose of 1.6×10¹⁸cm⁻² and energy of 180 keV and subsequent silicon ion implantation for amorphizing the substrate in the range of depth from about 50 nm to about 500 nm. It was annealed finally at 1300° C. for 6 hours.

In order to perform annealing at 1300° C., a special annealing furnace was designed with using SiC tube and lamp heating instead of quartz tube and electrical resister heating. It is expensive and short-lived, and thus increases the cost of SOI material.

If the third step to perform annealing process goes on at a lower temperature selected from 900° C. to 1250° C. and the duration chosen from 1 second to 20 hours, a conventional annealing furnace can be used. Because of amorphous enhanced diffusion effect, atoms in the amorphous region various still have relatively high diffusion coefficient even at a lower annealing temperature. The process can suppress silicon segregation in the buried oxide layer at a low temperature, and accordingly form the SOI material without threading dislocations in BOX, and without silicon islands and pinholes in the buried layer as shown in the FIG. 6.

FIG. 6 is a XTEM photograph of a sample, which is formed in the same implantation condition and the same amorphous process as in FIG. 5, but a low temperature annealing in the region from 900° C. to 1250° C. It can be seen from the photograph that the SOI material is free of threading dislocations and silicon islands. There is a band of damage subjacent the buried oxide layer, which is the remaining end-of-range damage. Because of the isolation of the buried oxide layer such damage will not affect electrical properties of the devices made in the top silicon layer, but it may absorb the contaminating metal impurity produced the first implantation process.

As described and further illustrated by the present invention and figures, the silicon islands and pinholes in the buried oxide layer are produced by silicon segregation in an over-high annealing temperature. In order to eliminate silicon islands in the formed SOI material, the present invention proposes following process: mounting the SOI wafer to a holder, holding a temperature below 100° C., implanting silicon ion though the top polished surface into the SOI wafer at a dose in the region from 5×10¹³cm⁻² to 5×10¹⁵cm⁻² and a energy in the region from 100 keV to 500 keV. In this way, an amorphous region with the buried oxide layer in it will be formed, but the top layer in the vicinity of the front wafer surface keeps its single crystal structure. And then it is annealed at a temperature above 900° C. and below 1250° C. in a conventional annealing furnace and in an inert ambient atmosphere. There is no oxygen diffusing outwards, if only amorphous region does not extend to the top Si layer too much, which is shown by the XTEM photograph in FIG. 7.

FIG. 7 is a XTEM photograph of a sample, which is formed as in FIG. 5 and then silicon self-implantation is performed for forming amorphous region and subsequently annealed at a temperature in the range from 900° C. to 1250° C. It retains the single crystal structure in the top silicon layer and smooth interface, such as in FIG. 5. However, it eliminates silicon islands in the buried layer. In the figure, there appear some damages beneath the lower interface of the buried oxide layer, which result from residual end-of-range damage.

In this sample, there are no threading dislocations in the top layer, nor silicon islands in the thicker buried oxide layer prepared by SIMOX method. To the best knowledge of the inventor, such a remarkably good SOI sample is the first one.

In order to improve the separation technique by implantation of nitrogen and to solve the problems existing in the separation by implantation of nitrogen (SIMNI) and the separation by implantation of oxygen and nitrogen (SIMON), a similar set of steps are proposed for successfully forming high quality of SOI material fabricated by SIMNI or SIMON.

If a p-type (100) silicon substrate of 500° C. temperature is implanted by N⁺ ion at 160 keV energy and 1.0×10¹⁸cm⁻² dose, and subsequently annealed at high temperature as in the conventional process, the formed buried nitride layer will be a polycrystal one. But if it is implanted subsequently by O⁺ ion at 2×10¹⁷cm⁻² dose and aforesaid energy after the N⁺ ion implantation, and then annealed at high temperature, the formed buried layer will be an amorphous one. However, if this implanted oxygen dose is lower, there emerges a polycrystalline silicon in the top silicon layer near amorphous buried oxynitride layer, which will disturb the formation of the sharp interface. If the dose of additional implanted oxygen is higher, nitrogen bubble will be formed insides the buried layer. All of these are the reason for the low diffusion coefficient of nitrogen atom in the silicon nitride or silicon oxynitride layer.

In accordance with the present invention, after the implantation of N⁺ ions or N⁺, O⁺ ions an amorphous process will be carried out by silicon self-implantation at room temperature or liquid nitrogen temperature, with implantation energy in the region from 100 keV to 500 keV and dose in the region from 5×10¹³cm⁻² to 5×10¹⁵cm⁻². In the precondition of keeping single crystal structure on silicon surface, an amorphous region will be formed beneath the surface, in which the buried oxynitride layer will be formed. The implanted ions may be germanium ion, inert gas ions or oxygen ion as desired.

Subsequent is an annealing process at a temperature in the region from 900° C. to below the silicon melting. In the end of the annealing process, a sharp and smooth interface is formed without polycrystalline silicon between the top silicon layer and the buried oxynitride layer. The formed buried oxynitride layer is a uniform amorphous layer free of bubbles. Because of the enhanced diffusion of various atoms in the amorphous region, the nitrogen atom, staying in the top silicon layer, rapidly migrates to buried oxynitride layer in the annealing process. The top silicon layer returns to single crystal silicon in the recrystallization process.

In conclusion, because of the introduction of amorphous process by ion implantation, the diffusion coefficient of various atoms increases greatly in the amorphous region of the present invention. Driven by thermodynamic potential, chemical potential and stress, the whole system rapidly recombines according to the lowest free energy principle in the annealing process. Therefore, for application to improve SIMOX method, the present invention can realize under a lower temperature annealing to eliminate the threading dislocation in the top layer and to restrain the production of silicon islands and pinholes. For application to improve SIMNI or SIMON methods, the present invention can avoid the emergence of polycrystalline layers. In accordance with present invention, any modification, substitution or amelioration based on present invention will be contained in the scope of the present invention's claims.

1. A method for fabricating a silicon-on-insulator (SOI) material by using an implanting oxygen ions into a silicon containing substrate having a major surface, comprising the steps of:
(1) implanting oxygen ions at a first dose and a first energy through said major surface into said silicon containing substrate controlled at a first temperature;
(2) implanting second kind of ions at a second dose and a second energy through said major surface into said silicon containing substrate at a second temperature below 100° C., to form an amorphous region beneath the major surface and to keep the original structure in the major surface of said silicon containing substrate;
(3) annealing aforesaid silicon containing substrate at a third temperature to form a buried oxide layer by combining oxygen implanted in step (1) with silicon in the substrate, and a top silicon layer including the said major surface isolated by the buried oxide layer.

2. The method of claim 1 wherein the said third temperature is chosen to be in the region from 1250° C. to below silicon melting point, eliminating the threading dislocations in the top silicon layer and reducing the surface dislocations to the lowest density to form SOI material.

3. The method of claim 1 wherein the said third temperature is selected in the range from 900° C. to 1250° C., eliminating the threading dislocations in the top silicon layer, and silicon islands and pinholes in buried oxide layer to form SOI material.

4. The method of claim 1 wherein the said first dose is determined by the desired thickness of said buried oxide layer, which will be formed after said annealing process in the step (3).

5. The method of claim 4 wherein the said first dose is in the range from 1×10¹⁶cm⁻² to 5×10¹⁸cm⁻².

6. The method of claim 1 wherein the said first energy is chosen to form enough depth of said buried oxide layer after said annealing process in step (3), so as to form a desired thickness of the top silicon layer.

7. The method of claim 6 wherein the said first energy is in the range from 50 keV to 400 keV.

8. The method of claim 1 wherein the said first temperature is chosen to keep the original structure in said major surface of said silicon containing substrate in the first ion implanting process.

9. The method of claim 8 wherein the said first temperature is in the range from 450° C. to 700° C.

10. The method of claim 1 wherein the said second energy is chosen in the range from 30 keV to 5 MeV to form an amorphous region beneath the said major surface and to keep the original structure in the major surface of said silicon containing substrate during the implantation in step (2).

11. The method of claim 1 wherein the said second dose is chosen in the range from 1×10¹³cm⁻² to 5×10¹⁶cm⁻² to form an amorphous region beneath the major surface containing both a majority of top silicon layer and all the buried oxide layer, which is formed in step (3).

12. The method of claim 1 wherein the said second kind of ion is silicon ion.

13. The method of claim 1 wherein the said second kind of ion is germanium ion.

14. The method of claim 1 wherein the said second kind of ion is inert gas ion.

15. The method of claim I wherein the said second kind of ion is oxygen ion.

16. A method for eliminating silicon islands and pinholes in the buried oxide layer of SOI material formed by using SIMOX method, comprising the steps of:
(1) implanting silicon ion, germanium ion, inert gas ion or oxygen ion at a dose and an energy into SOI material containing top silicon layer and buried oxide layer at a temperature below 100° C., to form an amorphous region including said buried oxide layer and to keep the original structure in vicinity of said major surface;
(2) annealing aforesaid SOI material at a temperature in the range from 900° C. to 1250° C. to restore structure of every layer and to eliminate silicon islands and pinholes in said buried oxide layer.

17. The method of claim 16 wherein the said energy is in the range from 30 keV to 5 MeV.

18. The method of claim 16 wherein the said dose is in the range from 1×10¹³cm⁻² to 5×10¹⁶cm⁻².

19. A method for forming high quality of SOI material on a silicon containing substrate having a major surface by using SIMNI method, comprising the steps of:
(1) implanting nitrogen at a first dose and a first energy though said major surface into said silicon containing substrate controlled at a first temperature;
(2) implanting second kind of ion at a second dose and a second energy though said major surface into said silicon containing substrate at a second temperature below 100° C., to form an amorphous region beneath said major surface and to keep the original structure in said major surface of the silicon containing substrate; and
(3) annealing aforesaid silicon containing substrate at a third temperature in the range from 900° C. to below the melting point of silicon, to combine the first implanted nitrogen and silicon and to form a buried nitride layer and a top silicon layer, which includes said major surface, isolated by the buried nitride layer.

20. The method of claim 19 wherein the said first dose is chosen to form a desired thickness of said buried nitride layer after said annealing process in step (3).

21. The method of claim 20 wherein the said first dose is in the range from 1×10¹⁶cm⁻² to 5×10¹⁸cm⁻².

22. The method of claim 19 wherein the said first energy is chosen to form enough depth of said buried nitride layer after said annealing process in step (3), so as to form a desired thickness of the top silicon layer.

23. The method of claim 22 wherein the said first energy is in the range from 50 keV to 400 keV.

24. The method of claim 19 wherein the said first temperature is chosen to keep the original structure in vicinity of said major surface on silicon containing substrate in said first implantation process of step (1).

25. The method of claim 24 wherein the said first temperature is in the range from 450° C. to 700° C.

26. The method of claim 19 wherein the said second energy is chosen in the range from 30 keV to 5 MeV to form an amorphous region beneath the said major surface and to keep the original structure in the major surface of said silicon containing substrate during the implantation in step (2).

27. The method of claim 19 wherein the said second dose is chosen in the range from 1×10¹³cm⁻² to 5×10¹⁶cm⁻² to form an amorphous region beneath the major surface containing both a majority of top silicon layer and all the buried oxide layer, which is formed in step (3).

28. The method of claim 19 wherein the said second kind of ion is silicon ion.

29. The method of claim 19 wherein the said second kind of ion is germanium ion.

30. The method of claim 19 wherein the said second kind of ion is inert gases ion.

31. The method of claim 19 wherein the said second kind of ion is oxygen ion.

32. The method of claim 19 wherein further comprising an oxygen ion implantation process before said step (2) at the same energy as the first one, at a dose for easily forming amorphous structure from buried oxynitride layer, which will be formed in the annealing process of step (3).

33. The method of claim 32 wherein selecting the second ion implanting dose and energy in step (2) for forming an amorphous region beneath said major surface in a majority of top silicon layer and all the buried oxynitride layer, which will be formed in annealing process of step (3); for keeping the original structure in said major surface of silicon containing substrate; and for enhancing the diffusion of various atoms in amorphous region, especially first implanted nitrogen, in the annealing process, to form a good insulating buried layer and a sharp interface between the top layer and the buried layer.
